(19) United States
(12) Patent Application Publication
(10) Pub. No.: US 2026/0140692 A1
(43) Pub. Date: May 21, 2026

(54) INTERFERENCE PREVENTION CIRCUIT FOR AUDIO SYSTEM

(71) Applicant: Harman International Industries, Incorporated, Stamford, CT (US)

(72) Inventors: Yanmei HAN, Shenzhen (CN); Ebing SHEN, Shenzhen (CN)

(21) Appl. No.: 18/950,654

(22) Filed: Nov. 18, 2024

(51) Int. Cl. G06F 3/16; H03G 3/32; H04R 3/04

(52) U.S. Cl. CPC G06F 3/165; G06F 3/162; H03G 3/32; H04R 3/04; H04R 2430/01; H04R 2499/13

(57) ABSTRACT

An audio device includes an input circuit configured to receive an audio input signal; an output circuit configured to output an audio output signal; and an isolation circuit including: a resistive opto-isolator including a light source configured to emit an amount of light therefrom in response to a control signal from a user interface, wherein the control signal is indicative of a desired gain for one or more loudspeakers to transmit the audio output signal into a listening environment; and at least one detector including a resistance value and being optically coupled to the light source such that the at least one detector detects the amount of light being emitted from the light source and the resistance value changes based on the detected amount of light for the one or more loudspeakers to transmit the audio output signal at the desired gain.

### TECHNICAL FIELD

The present disclosure generally relates to a circuit for preventing signal interference. More specifically, the present disclosure relates to a circuit for preventing signal interference in a vehicle audio system.

### BACKGROUND

Modern vehicles are provided with advance infotainment system for enhanced user experience. The infotainment system may be operably connected to multiple loudspeakers positioned at various locations within the vehicle cabin via cables. Due to the location of the loudspeakers, the cable may be up to five meters in length which may cause signal interferences. The long cable may further cause signal attenuation and tuning unevenness in some circumstances.

### SUMMARY

In one or more exemplary embodiments of the present disclosure, an audio device includes an input circuit configured to receive an audio input signal; an output circuit configured to output an audio output signal; and an isolation circuit including: a resistive opto-isolator including a light source configured to emit an amount of light therefrom in response to a control signal from a user interface, wherein the control signal is indicative of a desired gain for one or more loudspeakers to transmit the audio output signal into a listening environment; and at least one detector including a resistance value and being optically coupled to the light source such that the at least one detector detects the amount of light being emitted from the light source and the resistance value changes based on the detected amount of light for the one or more loudspeakers to transmit the audio output signal at the desired gain.

In one or more exemplary embodiments of the present disclosure, an isolation circuit includes a resistive opto-isolator (RO) including a light source configured to emit an amount of light therefrom in response to a control signal, wherein the control signal is indicative of a desired gain for one or more loudspeakers to transmit an audio output signal into a listening environment; and a detector associated with a resistance value and being optically coupled to the light source such that the detector detects the amount of light being emitted from the light source and the resistance value changes based on the detected amount of light for the one or more loudspeakers to transmit the audio output signal at the desired gain.

In one or more exemplary embodiments of the present disclosure, an audio device includes an input circuit configured to receive an audio input signal; an output circuit configured to output an audio output signal; and an isolation circuit including a resistive opto-isolator (RO) including a light source configured to emit an amount of light therefrom in response to a control signal that is indicative of a desired gain for one or more loudspeakers to transmit the audio output signal into a listening environment; and at least one detector being optically coupled to the light source such that the at least one detector detects the amount of light being transmitted from the light source to control the one or more loudspeakers to transmit the audio output signal at the desired gain into the listening environment.

### BRIEF DESCRIPTION OF THE DRAWINGS

For a better understanding of the invention and to show how it may be performed, embodiments thereof will now be described, by way of non-limiting example only, with reference to the accompanying drawings, in which:

FIG. 1 illustrates an example block topology of a vehicle system of one embodiment of the present disclosure.

FIG. 2 illustrates an example circuit diagram of an audio system including an isolation circuit for preventing signal interference of the vehicle audio system of one embodiment of the present disclosure.

FIG. 3 illustrates an example graph of transfer characteristics of a resistive opto-isolator of one embodiment of the present disclosure.

FIG. 4A illustrates a first equivalent circuit diagram of an adjustment circuit of the isolation circuit of embodiment of the present disclosure.

FIG. 4B illustrates a first equivalent circuit diagram of an adjustment circuit of the isolation circuit of embodiment of the present disclosure.

FIG. 4C illustrates a first equivalent circuit diagram of an adjustment circuit of the isolation circuit of embodiment of the present disclosure.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure proposes, among other things, a circuit for preventing signal interference. More specifically, the present disclosure proposes a circuit for preventing signal interference in a vehicle audio system.

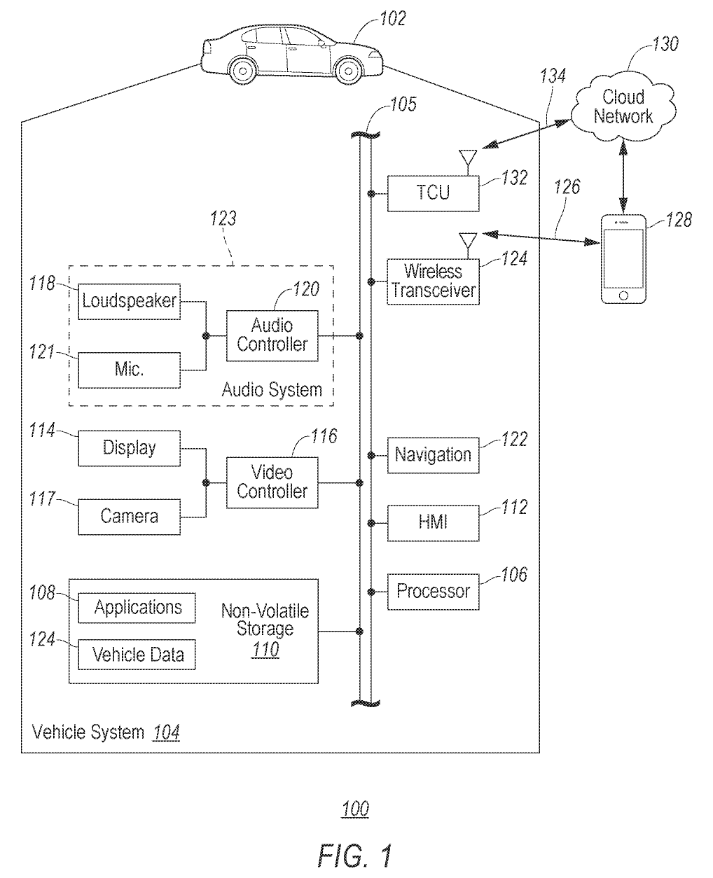

Referring to FIG. 1, an example block topology of a system 100 of one embodiment of the present disclosure is illustrated. A vehicle 102 may include various types of automobiles, crossover utility vehicle (CUV), sport utility vehicle (SUV), truck, recreational vehicle (RV), boat, plane, or other mobile machine for transporting people or goods. In many cases, the vehicle 102 may be powered by an engine. As another possibility, the vehicle 102 may be a battery electric vehicle (BEV), a hybrid electric vehicle (HEV) powered by both an internal combustion engine and one or move electric motors, such as a series hybrid electric vehicle (SHEV), a plug-in hybrid electric vehicle (PHEV), a parallel/series hybrid vehicle (PSHEV), or a fuel-cell electric vehicle (FCEV). It should be noted that the illustrated system 100 is merely an example, and more, fewer, and/or differently located elements may be used.

As illustrated in FIG. 1, the vehicle 102 may be provided with a vehicle system 104 including one or more processors 106 configured to perform instructions, commands, and other routines in support of the processes described herein. For instance, the vehicle system 104 may be configured to execute instructions of applications 108 to provide features such as vehicle operation controls, multimedia, or the like. Such instructions and other data may be maintained in a non-volatile manner using a variety of types of computer-readable storage medium 110. The computer-readable medium 110 (also referred to as a processor-readable medium or storage) includes any non-transitory medium that participates in providing instructions or other data that may be read by the processor 106 of the vehicle system 104. Computer-executable instructions may be compiled or interpreted from computer programs created using a variety of current and future programming languages and/or technologies.

The vehicle system 104 may be provided with one or more in-vehicle networks 105 configured to enable the communication between various components of the vehicle 102. The in-vehicle network 105 may be configured to support various communication protocol. For instance, the in-vehicle network 105 may be configured to support, but is not limited to, one or more of an I2C network, a controller area network (CAN), an Ethernet network, and a media-oriented system transport (MOST), as some examples. Furthermore, the in-vehicle network 105, or portions of the in-vehicle network 105, may be a wireless network accomplished via Bluetooth low-energy (BLE), Wi-Fi, or the like.

The vehicle system 104 may be provided with various features allowing the vehicle users to interface with the vehicle system 104. For example, the vehicle system 104 may receive input from human machine interface (HMI) controls 112 connected to the in-vehicle network 105 and configured to provide for user interaction with the vehicle 102. As an example, the vehicle system 104 may interface with one or more buttons, switches, knobs, touch screen or other HMI controls configured to invoke functions on the vehicle system 104 (e.g., navigation, audio/video playback, and etc.).

Any number of controllers (shown or not shown) within the vehicle system 104 may also drive or otherwise communicate with one or more displays 114 configured to provide visual output to vehicle users by way of a video controller 116 through the in-vehicle network 105. In some cases, the display 114 may be a touch screen further configured to receive user touch input via the video controller 116, while in other cases the display 114 may be a display only, without touch input capabilities. In addition, any number of controllers of the vehicle system 104 may also drive or otherwise communicate with one or more cameras 117 configured to provide video input by way of the video controller 116 through the in-vehicle network 105. The cameras 117 may include one or more in-cabin camera configured to capture images within the cabin of the vehicle 102 such that the vehicle system 104 may determine the occupancy of the vehicle 102 (e.g., the number of users inside the vehicle cabin and the location of the users).

Any number of controllers within the vehicle system 104 may also drive or otherwise communicate with one or more loudspeakers 118 configured to provide audio output to vehicle users by way of an audio controller 120 through the in-vehicle network 105. Any number of controllers within the vehicle system 104 may also drive or otherwise communicate with one or more microphones 121 configured to receive an audio input by way of the audio controller 120 through the in-vehicle network 105. The audio controller 120 in combination with the loudspeakers 118 and the microphones 121 constitutes an audio system 123 of the vehicle 102. It is noted that although the audio system 123 only includes three components as illustrated in the example with reference to FIG. 1, the present disclosure is not limited thereto. The audio system 123 may include various other components that are not illustrated in the example with reference to FIG. 1. For instance, the audio system 123 may include one or more hardware circuits configured to prevent/reduce signal interference of the audio system 123 (to be discussed in detail below).

The vehicle system 104 may also be provided with navigation and route planning features through a navigation controller 122 connected to the in-vehicle network 105 and configured to calculate navigation routes responsive to user input via e.g., the HMI controls 112, and output planned routes and instructions via the loudspeaker 118 and/or the display 114 through the audio controller 120 and/or the video controller 116. Location data that is needed for navigation may be determined by the communication with multiple satellites. Map data used for route planning may be stored in the storage 110 as a part of the vehicle data 125. Navigation software may be stored in the storage 110 as one of the vehicle applications 108.

The vehicle system 104 may also be provided with wireless communication capabilities via a wireless transceiver 124 connected to the in-vehicle network 105 and configured to wirelessly communicate with a mobile device 128 of vehicle users via a wireless connection 126. The mobile device 128 may be any of various types of portable computing devices, such as cellular phones, tablet computers, wearable devices, smart watches, smart fobs, laptop computers, portable music players, or other device capable of communication with the vehicle system 104. The wireless transceiver 126 may be configured to support a variety of wireless communication protocols including Wi-Fi, Bluetooth, radio-frequency identification (RFID), near-field communication (NFC), and communicate with a compatible wireless transceiver (not shown) of the mobile device 128 to enable various functions. For instance, the vehicle user may perform audio and/or video phone calls by mobile device 128 through the vehicle system 104. Additionally or alternatively, the vehicle system 104 may be configured to access a cloud network 130 via the mobile device 128 through wireless connection technologies such as cellular network.

The vehicle system 104 may also be provided with a telematics control unit (TCU) 132 connected to the in-vehicle network 105 and configured to control telecommunication between vehicle 102 and the cloud network 130 through a wireless connection 134 (e.g., using a modem) in addition to or in lieu of via the mobile device 128. For instance, the vehicle system 104 may download and/or upload data from/to the cloud network 130 via the TCU 132 or through the mobile device 128. It is noted that the term cloud network is used as a general term in the present disclosure and may include any computing network involving servers, carriers, routers, computers, controllers, circuitry or the like configured to store data and perform data processing functions and facilitate communication between various entities.

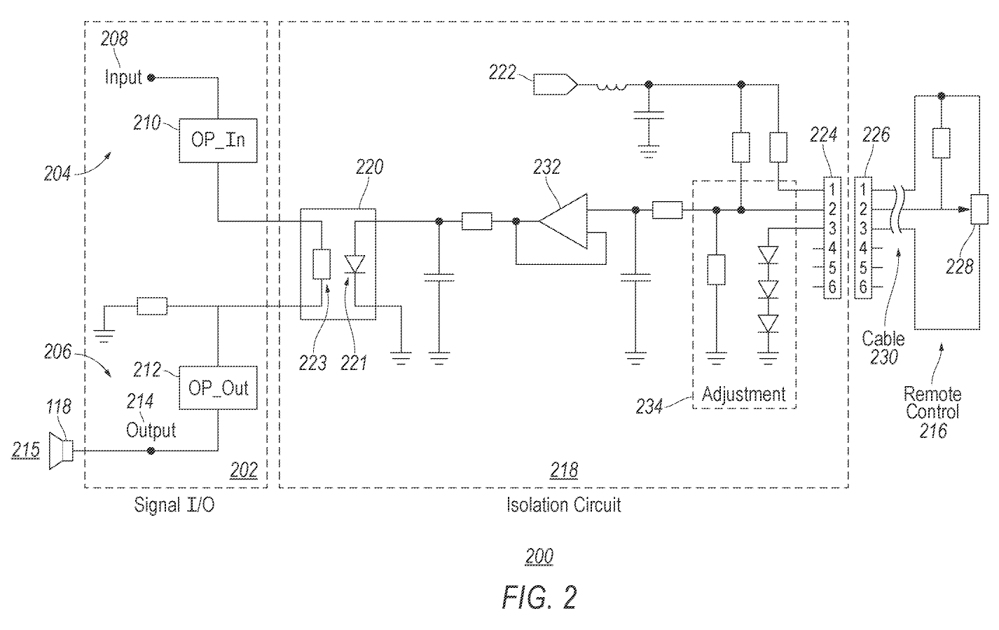

Referring to FIG. 2, an example circuit diagram 200 of the audio system 123 including an isolation circuit for preventing signal interference of the vehicle audio system of one embodiment of the present disclosure is illustrated. With continuing reference to FIG. 1, the audio system 123 may include an input/output (I/O) circuit 202 presented on the left side of the circuit diagram 200. The I/O circuit 202 may be integrated with and/or operably connected to the audio controller 120 and configured to provide audio input and output to the audio system 123.

More specifically, the I/O circuit 202 may include an input circuit 204 and an output end 206 configured to provide the signal input and output operations respectively. The input circuit 204 may include an input port 206 configured to receive audio input signals from one or more components of the vehicle system 104. For instance, the audio input signals may be received from the processor 106, storage 110 or other components via the in-vehicle network 105. Additionally or alternatively, the audio input signals may be received from the mobile device 128, and/or the cloud network 130. The input circuit 204 may be further include an input operational amplifier 210 configured amplify the audio input signals by increasing the gain.

The output circuit 206 of the I/O circuit 202 may include an output operational amplifier 212 configured to further amplify the audio signals to facilitate the output. The audio signals amplified by the output operational amplifier 212 may be fed to an output circuit 214 of the output circuit 206 for outputting. For instance, the output port 214 may be operably connected to one of more loudspeakers 118 to for outputting the amplifier audio signals into a listening environment 215.

The volume of the audio output may be controlled and adjusted by one or more controllers remotely connected to the signal I/O circuit 202 via one or more cables. continuing with example with reference to FIG. 2, a user interface circuit 216 (or remote control circuit 216) is illustrated on the right side of the circuit diagram 200. Due to the distance between the user interface circuit 216 and the I/O circuit 202, signal interference may occur therein between causing noise and attenuations. The present disclosure proposes an isolation circuit 218 connected between the I/O circuit 202 and the user interface circuit 216, and configured to isolate and/or prevent the signal interference. More specifically, the isolation circuit 218 utilizes a resistive opto-isolator (RO) 220 to connect between the input circuit 204 and the output circuit 206 of the I/O circuit 202 to provide the interference isolation. The RO 220 may include a light source 221 (e.g., right side) and a light detector 223 (e.g., left side) that are optically coupled and electrically isolated from each other. The light source 221 may include a light-emitting diode (LED) configured to emit light with the adjustable intensity by varying the input current. The detector 223 may include a semiconductor-based photoresistor configured to adjust the resistance based on the intensity of the light emitted by the light source 221.

The RO 220 may be associated with one or more predefined transfer characteristics. For instance, the resistance of the detector 223 may be negatively correlated to the light intensive and/or current of the light source 221. When the current flowing through the light source 222 increases, the resistance of the detector 223 decreases. Additionally, when the current flowing through the light source 222 decreases, the resistance of the detector 223 increases. The user may adjust the resistance of the detector 223 and thus the output power of the signal I/O circuit 202 by varying the current flowing through the light source 222 via the user interface circuit 216.

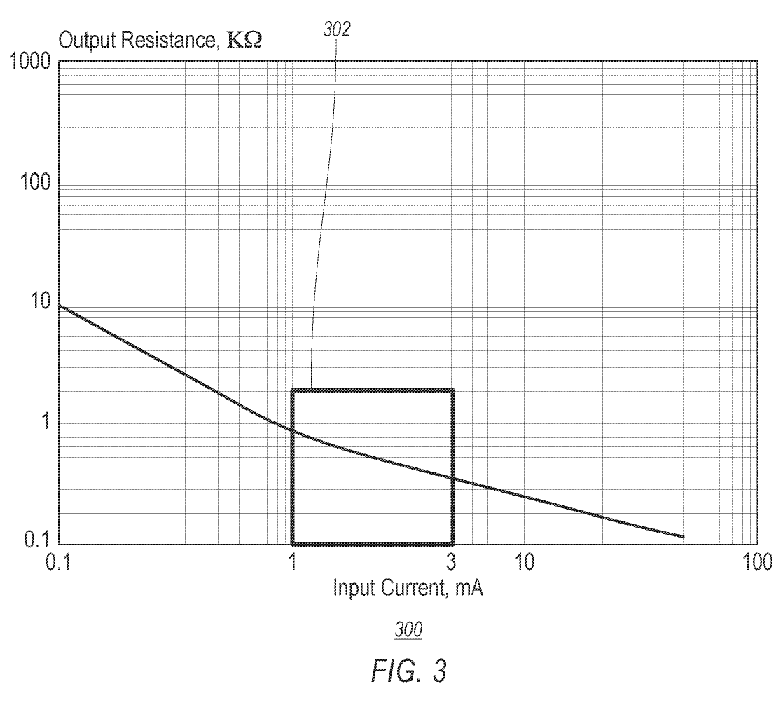

Referring to FIG. 3, an example graph 300 illustrating the transfer characteristics of the RO 220 of one embodiment of the present disclosure is illustrated. With continuing reference to FIGS. 1 and 2, the graph 300 is representative of the resistance characteristics of the RO 220 in response to the varying current input. More specifically, the horizontal axis of the graph 300 is representative of the current input to the light source 221 of the RO 220 in units of mA, and the vertical axis is representative of the resistance value of the detector 223 in units of kΩ. As illustrated in the graph 300, the resistance value is generally negatively correlated to the current input. For instance, when the input current is around 0.1 mA, the corresponding resistance value may be around 10 kΩ. When the input current is around 13 mA, the corresponding resistance value may be around 0.1 kΩ. To increase the control accuracy, a linear correspondence relationship between the current input and the resistance output may be preferred. In the present example, the transfer characteristics of the RO 220 is relatively linear in a region 302 between 1 and 3 mA current input. Therefore, the RO 220 may be configured to limit the operation region within the linear region 302. As illustrated in FIG. 3, the output resistance may be negatively correlated to the input current and thus the amount of light emitted by the light source 221. E.g., as the input c current (thus the amount of light) increases, the output resistance is reduced. More specifically, in the region 302, the output resistance may be inversely proportional to the input current (and thus the amount of light).

Referring to FIG. 2, The user interface circuit 216 may include a remote connector 226 configured to operably connect to the isolation circuit 218 via a receiver connector 224. The receiver connector 224 and the remote connector 226 may be implemented in various manners. As a non-limiting example, the receiver connector 224 and the remoted connector 226 may be configured to support modular connector interfaces such as registered jacks (RJ). The receiver connector 224 may be a jack whereas the remote connector 226 may be a plug configure to couple to the jack. In the example illustrated in FIG. 2, both of the receiver connector 224 and the remote connector 226 are provided with six pins corresponding to each other in support of RJ11, RJ12, RJ14, and/or RJ25 interfaces. Additionally or alternatively, the RJ45 interface in support of eight pins may be used in addition to and/or in lieu of the six-pin configurations. Additionally, the remote connector 226 may be connected to the rest of the user interface circuit 216 (e.g., the variable resistor 228) via a cable 230. Thus, while the remote connector 226 is locally positioned to the isolation circuit 218, the actual user interface circuit 216 may be remotely positioned to increase the flexibility. In one example, the user interface 216 may include a sliding element (e.g., a slider) or a rotating element (e.g., dial) to change or adjust the volume or gain of an audio output signal of the loudspeaker 118. For instance, the variable resistor 228 may be coupled to a rotating dial and/or slider remote from the isolation circuit to allow a user to adjust the output of the remote circuit 216 at a convenient location. In a real-life example, a vehicle user may adjust the volume of one or more loudspeakers 118 located at various location of the vehicle by rotating a volume dial located at the central console.

The user interface circuit 216 may further include a power source 222 configured to provide power to both the isolation circuit 218 and the user interface circuit 216. In the present example, the power source 222 is connected to a pin No. 1 and a pin No. 2 of the receiver connector 224 of the isolation circuit 218 Once the remote connector 226 is connected to the receiver connector 224, the power is sent to the user interface circuit 216 via a pin No. 1 and a pin No. 2 of the remote connector.

The isolation circuit 218 may be further provided with an adjustment circuit 234 configured to adjust an output signal based on the operations of the user interface circuit 216. (To be discussed in detail below.) In the present example, the output signal is provided by the pin No.2 of the receiver connector 224. The output signal from the adjustment circuit 234 may be sent to the RO 220 via an operational amplifier 232 configured to amplify the output signal and prevent signal attenuation.

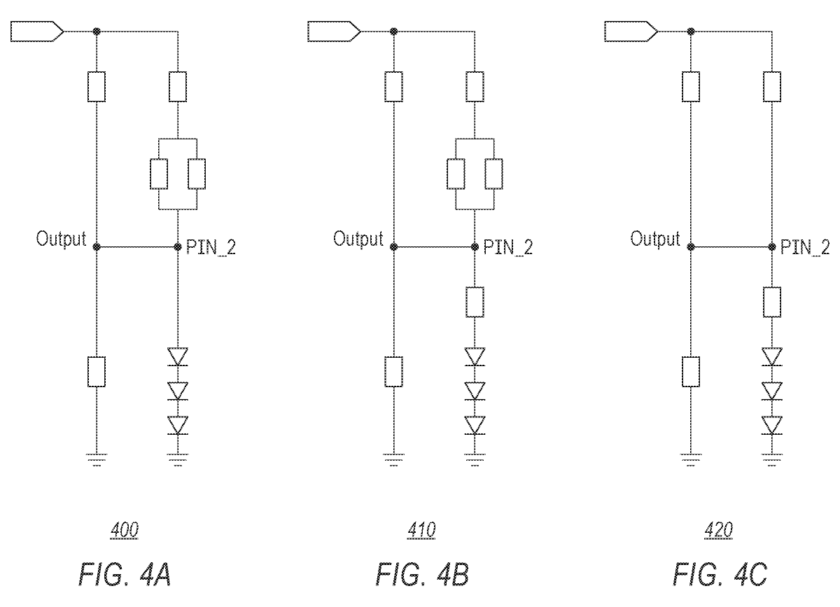

Referring to FIG. 4, equivalent circuit diagrams of an adjustment circuit 234 of the isolation circuit 218 of embodiment of the present disclosure are illustrated. Referring to FIG. 4A, an equivalent circuit diagrams 400 of an adjustment circuit 234 when the variable resistor 228 is turned to maximum resistance value is illustrated. With continuing reference to FIGS. 1 to 3, when the variable resistor 228 of the user interface circuit 216 is turned to the maximum, the voltage of the pin No. 2 of the receiver connector 224 reduces to the minimum. Therefore, the current flowing through the light source 221 of the RO 220 is the minimum which results in a maximum resistance of the detector 223. Therefore, the maximum volume on the output circuit 206 of the signal I/O circuit 202 is achieved.

There are a number of ways in which the variable resistor 228 may be implemented. In an non-limiting example, the variable resistor 228 may be a potentiometer having three terminals include two fixed terminals and an adjustable terminal with a sliding/rotating contact between the two fixed terminals that enables the resistance adjustability. In the example illustrated with reference to FIG. 2, when remote connector 226 includes six pins (e.g., an RJ12 plug), the two fixed terminals may be connected to pins No. 4 and No. 6, and the adjustable terminal may be connected to pin No. 5. The variable resistance may be achieved by sliding pin No. 5 between the pins No. 4 and No. 6. In the present example, the resistance of the variable resistor 228 is at the maximum when pin No. 5 is turned to pin No. 4.

Referring to FIG. 4B, an equivalent circuit diagrams 410 of an adjustment circuit 234 when the variable resistor 228 decreases from the maximum resistance value is illustrated. As the resistance value of the variable resistor 228 reduces (e.g., pin No. 5 is turned away from pin No. 4 toward pin No. 6), the voltage of the pin No. 2 of the receiver connector 224 increases. The increased voltage causes the current flowing through the light source 221 of the RO 220 to increase which results in a decreasing of the resistance of the detector 223 which in turn reduces the volume on the output circuit 206 of the signal I/O circuit 202.

Referring to FIG. 4C, an equivalent circuit diagrams 420 of an adjustment circuit 234 when the variable resistor 228 decreases to the minimum resistance value is illustrated. As the resistance value of the variable resistor 228 continues to decrease and arrives at the minimum value (e.g., pin No. 5 is turned to pin No. 6), the voltage of the pin No. 2 of the receiver connector 224 arrives at the maximum. In this case, the current flowing through the light source 221 of the RO 220 is the maximum which results in a minimum resistance of the detector 223. Therefore, the minimum volume on the output circuit 206 of the signal I/O circuit 202 is achieved.

It is recognized that the controllers as disclosed herein may include various microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, such controllers as disclosed utilizes one or more microprocessors to execute a computer-program that is embodied in a non-transitory computer readable medium that is programmed to perform any number of the functions as disclosed. Further, the controller(s) as provided herein includes a housing and the various number of microprocessors, integrated circuits, and memory devices ((e.g., FLASH, random access memory (RAM), read only memory (ROM), electrically programmable read only memory (EPROM), electrically erasable programmable read only memory (EEPROM)) positioned within the housing. The controller(s) as disclosed also include hardware-based inputs and outputs for receiving and transmitting data, respectively from and to other hardware-based devices as discussed herein.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. An audio device comprising:
an input circuit configured to receive an audio input signal;
an output circuit configured to output an audio output signal; and
an isolation circuit including:
a resistive opto-isolator (RO) including:
a light source configured to emit an amount of light therefrom in response to a control signal from a user interface, wherein the control signal is indicative of a desired gain for one or more loudspeakers to transmit the audio output signal into a listening environment; and
at least one detector including a resistance value and being optically coupled to the light source such that the at least one detector detects the amount of light being emitted from the light source and the resistance value changes based on the detected amount of light for the one or more loudspeakers to transmit the audio output signal at the desired gain.

2. The audio device of claim 1, wherein the isolation circuit further includes:
an adjustment circuit connected between the RO and a receiver connector, and configured to generate an adjustment voltage based on the control signal received via the receiver connector.

3. The audio device of claim 2, wherein the isolation circuit further includes:
an operational amplifier connected between the RO and the adjustment circuit, and configured to amplify the adjustment voltage and provide an amplified adjustment voltage to the light source of the RO such that the light source emitted the amount of light based on the amplified adjustment voltage.

4. The audio device of claim 2, wherein the isolation circuit further includes:
a power supply configured to supply electric power the adjustment circuit, and the user interface via the receiver connector.

5. The audio device of claim 4, wherein the receiver connector is configured to support at least one of the following standards: RJ11, RJ12 RJ14, RJ25 and RJ45.

6. The audio device of claim 5, wherein the power supply is further configured to supply electric power to user interface via at least a first pin and a second pin of the receiver connector.

7. The audio device of claim 1, wherein the resistance value of the at least one detector is negatively correlated to the amount of light being emitted from the light source.

8. The audio device of claim 1, wherein the RO is configured to operate in a linear region such that the resistance value of the at least one detector is inversely proportional to an input current flowing through the light source.

9. An isolation circuit comprising:
a resistive opto-isolator (RO) including:
a light source configured to emit an amount of light therefrom in response to a control signal, wherein the control signal is indicative of a desired gain for one or more loudspeakers to transmit an audio output signal into a listening environment; and
a detector associated with a resistance value and being optically coupled to the light source such that the detector detects the amount of light being emitted from the light source and the resistance value changes based on the detected amount of light for the one or more loudspeakers to transmit the audio output signal at the desired gain.

10. The isolation circuit of claim 9, further comprising:
an adjustment circuit connected between the RO and a receiver connector, and configured to generate an adjustment voltage based on a control signal received from a user interface via the receiver connector.

11. The isolation circuit of claim 10, further comprising:
an operational amplifier connected between the RO and the adjustment circuit, wherein the operational amplifier is configured to amplify the adjustment voltage and to provide an amplified adjustment voltage to the light source of the RO such that the light source emitted the amount of light based on the amplified adjustment voltage.

12. The isolation circuit of claim 10, further comprising:
a power supply configured to supply electric power the adjustment circuit, and the user interface via the receiver connector.

13. The isolation circuit of claim 12, further comprising: wherein the receiver connector is configured to support at least one of the following standards: RJ11, RJ12 RJ14, RJ25 and RJ45.

14. The isolation circuit of claim 13, wherein the power supply is further configured to supply electric power to a user interface via at least a first pin and a second pin of the receiver connector.

15. The isolation circuit of claim 9, wherein the resistance value of the detector is negatively correlated to the amount of light being emitted from the light source.

16. The isolation circuit of claim 9, wherein the RO is configured to operate in a linear region such that the resistance value of the detector is inversely proportional to an input current flowing through the light source.

17. An audio device comprising:
an input circuit configured to receive an audio input signal;
an output circuit configured to output an audio output signal; and
an isolation circuit including:
a resistive opto-isolator (RO) including:
a light source configured to emit an amount of light therefrom in response to a control signal that is indicative of a desired gain for one or more loudspeakers to transmit the audio output signal into a listening environment; and
at least one detector being optically coupled to the light source such that the at least one detector detects the amount of light being transmitted from the light source to control the one or more loudspeakers to transmit the audio output signal at the desired gain into the listening environment.

18. The audio device of claim 17, wherein the isolation circuit further includes:
an adjustment circuit connected between the RO and a receiver connector, and configured to generate an adjustment voltage based on the control signal received via the receiver connector.

19. The audio device of claim 18, wherein the isolation circuit further includes:
an operational amplifier connected between the RO and the adjustment circuit, and configured to amplify the adjustment voltage and provide an amplified adjustment voltage to the light source of the RO such that the light source emitted the amount of light based on the amplified adjustment voltage.

20. The audio device of claim 18, wherein the receiver connector is configured to support at least one of the following standards: RJ11, RJ12 RJ14, RJ25 and RJ45.
